(19) United States
(12) Patent Application Publication
(10) Pub. No.: US 2026/0039267 A1
(43) Pub. Date: Feb. 5, 2026

(54) AMPLIFYING APPARATUS

(71) Applicant: Fujitsu Limited, Kawasaki-shi (JP)

(72) Inventors: AKIHIKO KOMATSUZAKI, Kawasaki (JP); TOSHIYUKI AOKI, Mitaka (JP); KEIGO TOYODA, Kawasaki (JP); MITSUHARU HAMANO, Sendai (JP); SATOSHI MATSUBARA, Kawasaki (JP)

(73) Assignee: Fujitsu Limited, Kawasaki-shi (JP)

(21) Appl. No.: 19/280,222

(22) Filed: Jul. 25, 2025

(30) Foreign Application Priority Data
Aug. 5, 2024 (JP) 2024-129211

(51) Int. Cl. H03G 3/00; H03F 1/02

(52) U.S. Cl. CPC H03G 3/001; H03F 1/0288

(57) ABSTRACT

An amplifying apparatus includes: clip processor circuitry configured to perform clip processing, on a basis of the power of a first signal, so as to multiply the power of the first signal by a clip correction value such that the power of the first signal falls within a specified range; gain processor circuitry configured to perform gain processing so as to multiply the power of the first signal subjected to the clip processing by a gain correction value, and further configured to input to analog converter (DAC) the signal after the gain processing; and a gain adjuster configured to restore the power of the first signal output from the DAC to the power before the gain processing and the clip processing, and further configured to input the signal to a carrier amplifier.

### CROSS-REFERENCE TO RELATED APPLICATION

This application is based upon and claims the benefit of priority of the prior Japanese Patent Application No. 2024-129211, filed on Aug. 5, 2024, the entire contents of which are incorporated herein by reference.

### FIELD

The present disclosure relates to an amplifying apparatus.

### BACKGROUND

For instance, in a wireless communication system that supports fifth-generation communication, a communication apparatus may use an amplifying apparatus referred to as a Doherty amplifier to achieve high amplification efficiency for a wide bandwidth.

The Doherty amplifier includes, for instance, a carrier amplifier and a peak amplifier. The Doherty amplifier has, for instance, a mechanism in which only the carrier amplifier operates when the input signal level is low, while both the carrier amplifier and the peak amplifier operate when the input signal level is high. When a higher power signal is input, the output signal level of the carrier amplifier reaches saturation power. As a result, the carrier amplifier no longer produces amplification effects, and the peak amplifier amplifies the signal.

Furthermore, the input of the signal to the Doherty amplifier is performed, for instance, through a Digital-to-Analog Converter (DAC) that converts a digital signal into an analog signal. The Doherty amplifier amplifies the level of the input analog signal through the peak amplifier and the carrier amplifier.

Technologies related to amplifying apparatuses are described in WO 2005/124994, Japanese Utility Model Application Publication No. S58-144931, and Japanese Patent Application Publication No. 2016-136688.

### SUMMARY

An amplifying apparatus having a carrier amplifier and a digital-to-analog converter (DAC) outputting to the carrier amplifier, and outputting a first signal to be input after amplification thereof through the DAC and the carrier amplifier, the amplifying apparatus includes, a clip processor configured to perform clip processing, on a basis of the power of the first signal, so as to multiply the power of the first signal by a clip correction value such that the power of the first signal falls within a specified range, a gain processor configured to perform gain processing so as to multiply the power of the first signal subjected to the clip processing by a gain correction value, and further configured to input to the DAC the signal after the gain processing, and a gain adjuster configured to restore the power of the first signal output from the DAC to the power before the gain processing and the clip processing, and further configured to input the signal to the carrier amplifier.

The object and advantages of the disclosure will be realized and attained by means of the elements and combinations particularly pointed out in the claims.

It is to be understood that both the foregoing general description and the following detailed description are exemplary and explanatory and are not restrictive of the disclosure.

### BRIEF DESCRIPTION OF DRAWINGS

FIG. 1 is a diagram illustrating a configuration example of a wireless communication system 100.

FIG. 2 is a diagram illustrating a configuration example of the base station apparatus 200.

FIG. 3 is a diagram illustrating an example of the function blocks of the amplifying apparatus 251.

FIG. 4 is a diagram illustrating an example of the function blocks of the digital Doherty signal processing unit 13.

FIG. 5 is a diagram illustrating an example of the flowchart of the carrier amplifier signal processing S100.

FIG. 6 is a diagram illustrating an example of the image of a level indicator in each processing unit.

### DESCRIPTION OF EMBODIMENTS

As the output of the DAC decreases from full-scale power, the Signal-to-Noise (S/N) ratio decreases (degrades). As a result, the output from the DAC to the carrier amplifier that operates effectively at low power worsens the S/N ratio, potentially leading to the degradation of wireless characteristics.

### First Embodiment

A first embodiment will be described.

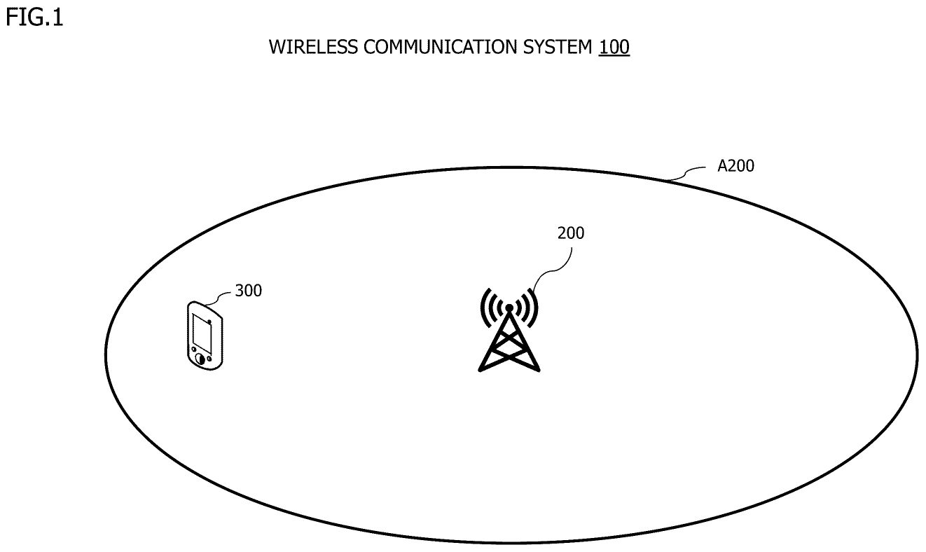

FIG. 1 is a diagram illustrating a configuration example of a wireless communication system 100. The wireless communication system 100 has a base station apparatus 200 and a terminal apparatus 300. The wireless communication system 100 is a wireless communication system that wirelessly connects the base station apparatus 200 and the terminal apparatus 300 and relays communications between the terminal apparatus 300 and other communication apparatuses.

The base station apparatus 200 is an apparatus that wirelessly connects to the terminal apparatus 300 and performs wireless communication, and is, for instance, an eNodeB or a gNB. The base station apparatus 200 relays communications between the terminal apparatus 300 and other communication apparatuses through a network. The base station apparatus 200 forms a communication area (cell) A200 and wirelessly connects to the terminal apparatus 300 positioned within the communication area A200.

The terminal apparatus 300 is a communication apparatus that wirelessly connects to the base station apparatus 200 and transmits and receives data, and is, for instance, a smartphone or a tablet.

### Configuration Example of Base Station Apparatus 200

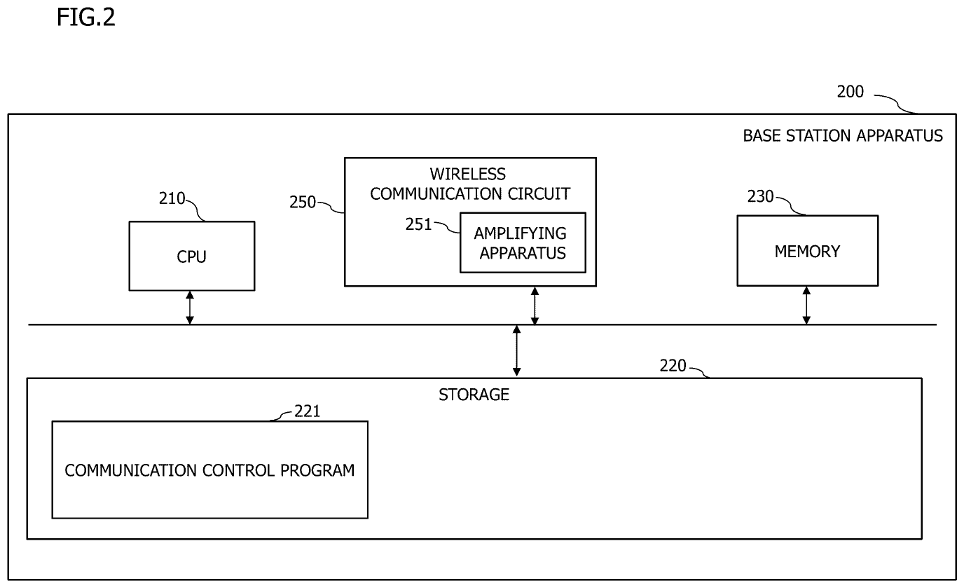

FIG. 2 is a diagram illustrating a configuration example of the base station apparatus 200. The base station apparatus 200 has a Central Processing Unit (CPU) 210, a storage 220, a memory 230, and a wireless communication circuit 250.

The storage 220 is an auxiliary storage device,, e.g., a flash memory, a Hard Disk Drive (HDD), or a Solid State Drive (SSD), which stores programs or data. The storage 220 stores a communication control program 221.

The memory 230 is an area into which the programs stored in the storage 220 are loaded. Furthermore, the memory 230 may also be used as an area in which the programs store data.

The wireless communication circuit 250 is an apparatus that allows for wireless communication with the terminal apparatus 300. The base station apparatus 200 transmits and receives signals (messages) to and from the terminal apparatus 300 through the wireless communication circuit 250.

The wireless communication circuit 250 has an amplifying apparatus 251. The amplifying apparatus 251 amplifies the level (power) of a signal and outputs the amplified signal. When transmitting a signal, the base station apparatus 200 amplifies the level through the amplifying apparatus 251 and transmits the amplified signal through the wireless communication circuit 250.

The CPU 210 is a processor that loads the programs stored in the storage 220 into the memory 230, executes the loaded programs, constructs each unit, and implements each processing.

By executing the communication control program 221, the CPU 210 constructs a communication control unit and performs communication control processing. The communication control processing is processing to control wireless connection and wireless communication with the terminal apparatus 300. Furthermore, the communication control processing includes relay processing for the signals transmitted and received by the terminal apparatus 300.

### Amplifying Apparatus 251

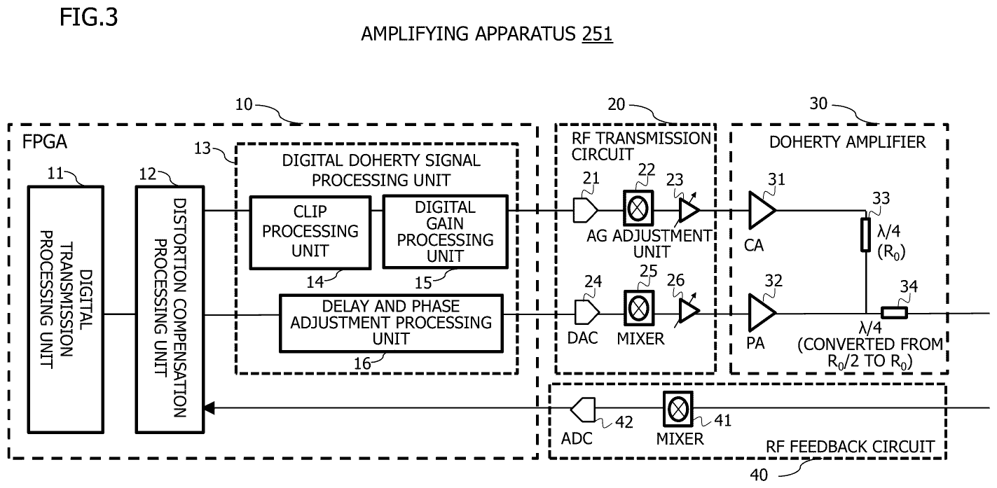

FIG. 3 is a diagram illustrating an example of the function blocks of the amplifying apparatus 251. The amplifying apparatus 251 has a Field-Programmable Gate Array (FPGA) 10, a Radio Frequency (RF) transmission circuit 20, a Doherty amplifier 30, and an RF feedback circuit 40.

The FPGA 10 is an integrated circuit capable of changing the logic of a digital circuit. The FPGA 10 has a digital transmission processing unit 11, a distortion compensation processing unit 12, and a digital Doherty signal processing unit 13.

For instance, the digital transmission processing unit 11 performs transmission processing on a signal received through a network and converts it into an In-Phase/Quadrature-Phase (I/Q) signal. The digital transmission processing unit 11 outputs the I/Q signal to the distortion compensation processing unit 12.

The distortion compensation processing unit 12 performs processing to compensate for nonlinear distortion within the carrier band. The distortion compensation processing unit 12 outputs the distortion-compensated signal to the digital Doherty signal processing unit 13.

The digital Doherty signal processing unit 13 performs processing on the signal that is to be output to the Doherty amplifier 30 through the RF transmission circuit 20.

The digital Doherty signal processing unit 13 has a clip processing unit 14, a digital gain processing unit 15, and a delay and phase adjustment processing unit 16.

The signal that is output to a Carrier Amplifier (CA) 31 of the Doherty amplifier 30 passes through the clip processing unit 14 and the digital gain processing unit 15.

The clip processing unit 14 corrects the level of the I/Q signal using a clip threshold. The clip threshold is a value that is determined on the basis of the saturation power, Peak-to-Average Power Ratio (PAPR), or the like of the carrier amplifier 31. Furthermore, the clip threshold may also be a value that is determined on the basis of the characteristics of the carrier amplifier, e.g., individual differences, and differs for each carrier amplifier. The clip processing unit 14 outputs the I/Q signal that has undergone the clip correction to the digital gain processing unit 15.

The digital gain processing unit 15 performs digital gain processing on the input I/Q signal. The digital gain processing unit 15 multiplies the I and Q components of the transmission signal by a fixed gain. The gain amount is, for instance, the difference between the full-scale power before the clip processing and the clip threshold. The digital gain processing unit 15 outputs the signal that has undergone the digital gain processing to the RF transmission circuit 20.

The delay and phase adjustment processing unit 16 adjusts the delay and phase of the I/Q signal and outputs the signal to a Peak Amplifier (PA) 32 of the Doherty amplifier 30 through the RF transmission circuit 20.

The RF transmission circuit 20 converts the digital signal into an analog signal, adjusts the transmission power level, and outputs the signal to the Doherty amplifier 30. The RF transmission circuit 20 has two paths for output, one for the peak amplifier 32 and the other for the carrier amplifier 31 of the Doherty amplifier 30.

The RF transmission circuit 20 has a DAC 21, a mixer 22, and an Analog Gain (AG) adjustment unit 23 on the path for the carrier amplifier 31, and a DAC 24, a mixer 25, and an Analog Gain adjustment unit 26 on the path for the peak amplifier 32.

The DACs 21 and 24 convert the digital signal into an analog signal and output the signal to the mixers 22 and 25. The mixers 22 and 25 modulate the signal into a carrier wave and output the modulated signal to the AG adjustment units 23 and 26. The AG adjustment units 23 and 26 adjust the transmission power level and output the adjusted signal to the Doherty amplifier 30.

For instance, the AG adjustment unit 23 restores the level (power) of the input signal, which has been adjusted through the clip correction and the digital gain processing described above, to the power at input (the power before the clip correction and the digital gain processing). In other words, the AG adjustment unit 23 adjusts the gain such that the transmission power level of the signal output to the Doherty amplifier 30 becomes equivalent to the transmission power level of the signal that would be output to the AG adjustment unit 23 without undergoing the clip correction and the digital gain processing described above. Note that the AG adjustment unit 26 handles signals that have not undergone the clip correction and the digital gain processing. Therefore, the AG adjustment unit 26 performs adjustment processing different from that performed by the AG adjustment unit 23.

The Doherty amplifier 30 has the carrier amplifier 31 and the peak amplifier 32. The Doherty amplifier 30 inputs the signals to the paths for the carrier amplifier 31 and the peak amplifier 32. The Doherty amplifier 30 performs phase adjustment for the output combination of the carrier amplifier 31 and the peak amplifier 32 using Δ/4 lines 33 and 34. The Doherty amplifier 30 amplifies the input signals and outputs a wireless signal, for instance, through the antenna of the wireless communication circuit 250. A portion of the signal output from the Doherty amplifier 30 is input to the RF feedback circuit 40 through a coupler.

The RF feedback circuit 40 has a mixer 41 and an Analog-to-Digital Converter (ADC) 42. The mixer 41 performs demodulation processing on the signal and outputs the demodulated signal to the ADC 42. The ADC 42 converts the analog signal into a digital signal and outputs the converted signal to the distortion compensation processing unit 12. The distortion compensation processing unit 12 generates a distortion compensation coefficient, which corrects amplitude or phase according to the level of a transmission signal, on the basis of the feedback signal, and performs distortion compensation on the output signal from the Doherty amplifier 30.

### Digital Doherty Signal Processing Unit 13

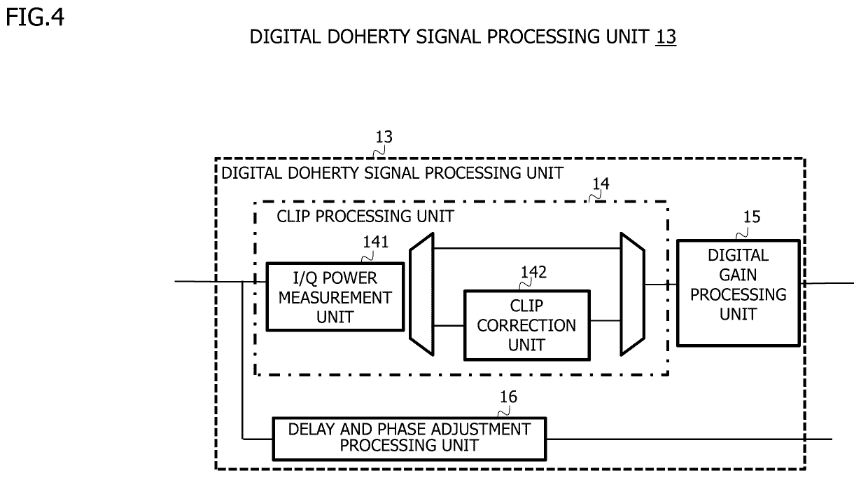

FIG. 4 is a diagram illustrating an example of the function blocks of the digital Doherty signal processing unit 13. The digital Doherty signal processing unit 13 has the clip processing unit 14, the digital gain processing unit 15, and the delay and phase adjustment processing unit 16. The digital gain processing unit 15 and the delay and phase adjustment processing unit 16 have been described above. Therefore, their descriptions will be omitted.

The clip processing unit 14 has an I/Q power measurement unit 141 and a clip correction unit 142. The I/Q power measurement unit 141 measures the power of the input I/Q signal and outputs the signal. The clip correction unit 142 performs clip correction on the IQ signal and outputs the signal to the digital gain processing unit 15. Note that the I/Q signal passes through the clip correction unit 142 or bypasses the clip correction unit 142 depending on the measured power.

Note that the delay and phase adjustment processing unit 16 may be provided in front of the clip processing unit 14.

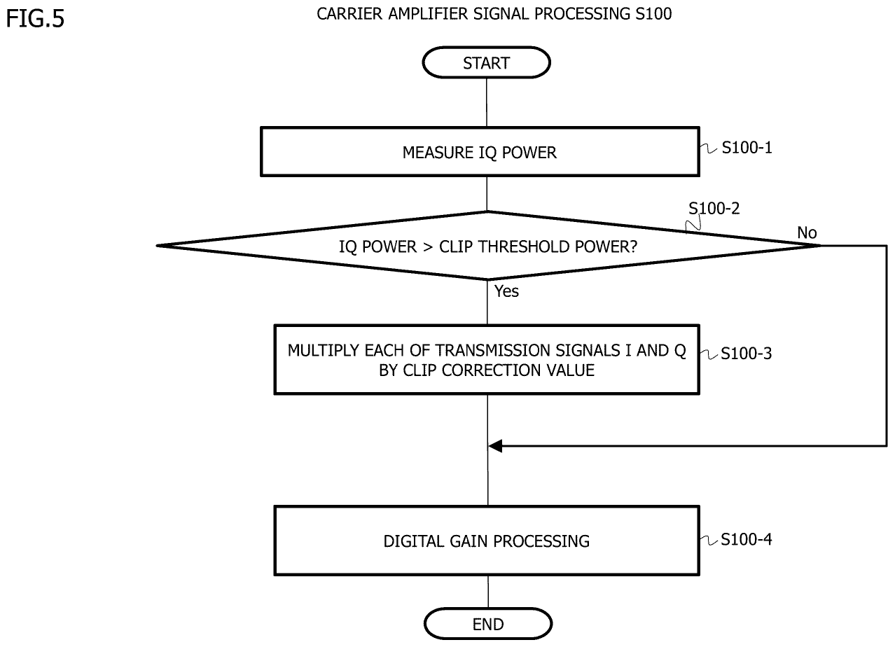

Hereinafter, signal processing for the signal input to the carrier amplifier in the digital Doherty signal processing unit 13 (referred to as carrier amplifier signal processing S100 below) will be described. FIG. 5 is a diagram illustrating an example of the flowchart of the carrier amplifier signal processing S100.

The I/Q power measurement unit 141 measures the power (IQ power) of the input signal for each sample (S100-1). A separator compares the IQ power with a clip threshold to identify whether the former is greater than the latter (S100-2). When the IQ power is greater than the clip threshold (Yes in S100-2), the separator multiplies each of the I (In-phase) and Q (Quadrature-phase) components of the signal by a clip correction value through the clip correction unit 142 (S100-3).

The clip correction value is calculated using, for instance, the following Formula 1.

$$\begin{matrix}[ Math . 1 ] & \\ Clip correction value = \sqrt{\frac{Clip threshold}{IQ power}} & Formula 1\end{matrix}$$

By calculating the clip correction value in Formula 1, the maximum power after the clip processing becomes the clip threshold.

When the IQ power is not greater than the clip threshold (No in S100-2), the separator outputs the signal by bypassing the clip correction unit 142.

The digital gain processing unit 15 performs digital gain processing on the signal that has undergone or has not undergone the clip correction (S100-3), and outputs the signal to the RF transmission circuit 20 to end the processing.

In the digital gain processing, the digital gain processing unit 15 multiplies each of the I and Q components of the signal by a digital gain correction value. The digital gain correction value is calculated using, for instance, the following Formula 2.

$$\begin{matrix}[ Math . 2 ] & \\ Digital gain correction value = \sqrt{\frac{Full - scale power}{Clip threshold}} & Formula 2\end{matrix}$$

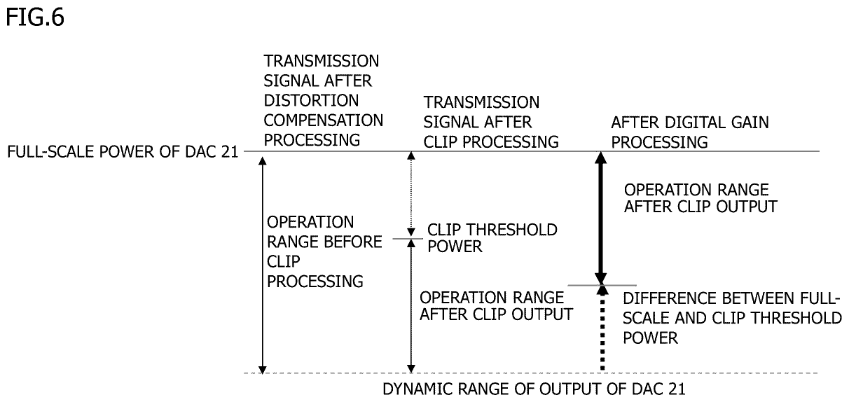

The digital gain correction value is, for instance, the difference between the full-scale power before the clip processing and the clip threshold power. FIG. 6 is a diagram illustrating an example of the image of a level indicator in each processing unit.

Note that the AG adjustment unit 23 of the RF transmission circuit 20 adjusts the level of the signal input to the carrier amplifier, that is, processing to reduce the power (level) by an amount amplified in the digital gain processing unit 15 (which may include the amount amplified through clip correction when the clip correction unit 142 has performed the clip correction).

The amplifying apparatus 251 in the first embodiment restricts the output to the DAC 21 that outputs the signal input to the carrier amplifier 31 of the Doherty amplifier 30. As a result, it is possible to restrict the power input to the carrier amplifier at the digital output stage, thereby reducing the full-scale power of the output to the DAC 21 while increasing the output level of the DAC 21 under low power conditions. In addition, it is possible to suppress a reduction in the S/N ratio.

In the transmission of a high-power signal, the signal input to the carrier amplifier is subjected to clip processing by the clip correction unit 142. Even if the signal is input to the carrier amplifier without undergoing the above processing, the saturation power of the carrier amplifier is reached. Therefore, the carrier amplifier no longer produces amplification effects, and the influence of this processing is minimal. In this case, since the signal that has not undergone the clip processing is amplified by the peak amplifier, the output of the Doherty amplifier is appropriately amplified.

### Other Embodiments

The configuration of the Doherty amplifier 30 illustrated in FIG. 3 is merely an example, and it may have a different configuration. The Doherty amplifier 30 only needs to be configured with a carrier amplifier and a peak amplifier and may also be a so-called inverse Doherty amplifier.

According to an aspect of the present disclosure, it is possible to suppress the degradation of wireless characteristics.

All examples and conditional language provided herein are intended for the pedagogical purposes of aiding the reader in understanding the disclosure and the concepts contributed by the inventor to further the art, and are not to be construed as limitations to such specifically recited examples and conditions, nor does the organization of such examples in the specification relate to a showing of the superiority and inferiority of the disclosure. Although one or more embodiments of the present disclosure have been described in detail, it should be understood that the various changes, substitutions, and alterations could be made hereto without departing from the spirit and scope of the disclosure.

What is claimed is:

1. An amplifying apparatus including a carrier amplifier and a digital-to-analog converter (DAC) outputting to the carrier amplifier, and outputting a first signal to be input after amplification thereof through the DAC and the carrier amplifier, the amplifying apparatus comprising:
clip processor circuitry configured to perform clip processing, on a basis of the power of the first signal, so as to multiply the power of the first signal by a clip correction value such that the power of the first signal falls within a specified range;
gain processor circuitry configured to perform gain processing so as to multiply the power of the first signal subjected to the clip processing by a gain correction value, and further configured to input to the DAC the signal after the gain processing; and
a gain adjuster configured to restore the power of the first signal output from the DAC to the power before the gain processing and the clip processing, and further configured to input the signal to the carrier amplifier.

2. The amplifying apparatus according to claim 1, wherein
the clip processor circuitry does not perform the clip processing when the power of the first signal is less than or equal to a first threshold.

3. The amplifying apparatus according to claim 2, wherein
the first threshold is determined on a basis of saturation power of the carrier amplifier.

4. The amplifying apparatus according to claim 3, wherein
the clip correction value is determined on a basis of the first threshold.

5. The amplifying apparatus according to claim 3, wherein
the clip correction value is determined on a basis of the power of the first signal.

6. The amplifying apparatus according to claim 1, wherein
the gain correction value is determined on a basis of full-scale power of the carrier amplifier.

7. The amplifying apparatus according to claim 2, wherein
the gain correction value is determined on a basis of the first threshold.

8. The amplifying apparatus according to claim 1, wherein
the carrier amplifier is provided in a Doherty amplifier, the Doherty amplifier further including a peak amplifier,
the clip processor circuitry does not perform the clip processing on a signal that is input to the peak amplifier, and
the gain processor circuitry does not perform the gain processing on the signal that is input to the peak amplifier.

9. An amplifying apparatus including a Doherty amplifier, a first digital-to-analog converter (DAC), and a second digital-to-analog converter (DAC), and outputting an input signal after amplification of power thereof, the Doherty amplifier including a carrier amplifier, a peak amplifier, a first input on a side of the carrier amplifier and a second input on a side of the peak amplifier, the first DAC being provided in front of the first input, and the second DAC being provided in front of the second input,
the amplifying apparatus comprising:
clip processor circuitry configured to perform clip processing, on a basis of power of a first signal branched off from the signal, so as to multiply the power of the first signal by a clip correction value such that the power of the first signal falls within a specified range;
gain processor circuitry configured to perform gain processing so as to multiply the power of the first signal subjected to the clip processing by a gain correction value, and further configured to input the signal after the gain processing to the first DAC; and
a gain adjuster configured to restore the power of the first signal output from the first DAC to the power before the gain processing and the clip processing, and further configured to input the signal to the carrier amplifier through the first input.

10. The amplifying apparatus according to claim 9, wherein
the clip processing and the gain processing are not performed on a second signal, which is branched off from the signal and differs from the first signal, and the second signal is input to the peak amplifier through the second DAC.
